(19) United States
(12) Patent Application Publication
(10) Pub. No.: US 2026/0219582 A1
(43) Pub. Date: Jul. 30, 2026

(54) PATTERN FORMING UNIT AND METHOD AND APPARATUS FOR ALIGNMENT

(71) Applicant: ORC MANUFACTURING CO., LTD., Tokyo (JP)

(72) Inventors: Akira NAKAZAWA, Machida-shi (JP); Yuki MASADA, Machida-shi (JP); Yuken NAKAMOTO, Machida-shi (JP)

(73) Assignee: ORC MANUFACTURING CO., LTD., Tokyo (JP)

(21) Appl. No.: 19/089,355

(22) Filed: Mar. 25, 2025

(30) Foreign Application Priority Data
Jan. 29, 2025 (JP) 2025-013077

(51) Int. Cl. G03F 7/00; G03F 1/42

(52) U.S. Cl. CPC G03F 7/70258; G03F 1/42; G03F 7/70025

(57) ABSTRACT

An apparatus for forming a pattern onto a substrate according to the present invention includes a table with a surface and a measuring system. A substrate with a plurality of pattern areas is mounted on the surface and at least one aperture is formed on the surface. The measuring system is configured to capture alignment marks formed on or in the substrate from the surface side, via the aperture. The aperture has a size that includes one pattern area and part of the surrounding boundary.

### BACKGROUND OF THE INVENTION

### 1. Field of the Invention

The present invention relates to an alignment system for the alignment of a mask (photomask) and a substrate, and especially the detection of alignment marks from the back-surface side of the substrate.

### 2. Description of the Related Art

In a pattern-forming unit such as a photolithography system, a laser-processing unit, etc., an alignment system captures alignment marks formed on the substrate and aligns the workpiece and/or mask based on the positions of the alignment marks. In the manufacturing process of a multi-layer semiconductor device, alignment marks are formed on the back surface side or an intermediate layer of the substrate, in addition to the front surface, to form a circuitry that electrically connects the front surface to the back surface side or forms a metallic layer as an intermediate layer.

To capture alignment marks that are formed on either the back surface side or the intermediate layer from the back-surface side, i.e., the table side of a stage, an optical unit for detecting the alignment marks is installed in the table. Gui et al. (US2002/0109825A1) and Fujishima (US2019/0278186A1) discloses such an alignment system. The alignment system detects the alignment marks by illuminating the alignment marks and imaging a reflected light via a camera or a microscope.

Usually, an alignment mark is minute on the micron order to carry out an alignment with high accuracy. On the other hand, the size of a die (chip), which is a pattern area on the substrate, depends upon characteristics or specification of the pattern-forming unit, the preliminary manufacturing process, etc.

For example, when forming a reticle pattern on a silicon wafer by a projection aligner, the size of the die (chip) to be formed on the silicon wafer depends upon the size of the reticle. In the case of a six-inch reticle, the size of the die can be determined to be a maximum of 26mm x 33mm.

### SUMMARY OF THE INVENTION

An apparatus for forming a pattern onto a substrate according to the present invention includes a table with a surface and a measuring system. A substrate with a plurality of pattern areas is mounted on the surface and at least one aperture is formed on the surface. The measuring system is configured to capture alignment marks formed on or in the substrate from the surface side, via the aperture. The aperture size includes one pattern area and part of the surrounding boundary.

An alignment system includes a table with a surface, a measuring system and a processor. A substrate with a plurality of pattern areas is mounted on the surface. At least one aperture is formed on the surface. The measuring system is configured to capture alignment marks formed on or in the substrate from the surface side, via the aperture. The processor is configured to calculate alignment-correcting values based on the positions of the alignment marks. The aperture size includes one pattern area and part of the surrounding boundary.

A method for aligning a substrate includes: a) mounting a substrate with a plurality of pattern areas on a surface of a table, at least one aperture being formed in the surface, the aperture size including one pattern area and part of the surrounding boundary; b) capturing alignment marks formed on or in the substrate from the surface side, via the aperture; and c) calculating alignment-correcting values based on the positions of the alignment marks.

### BRIEF DESCRIPTION OF THE DRAWINGS

The present invention will be better understood from the description of the preferred embodiment of the invention set forth below together with the accompanying drawings, in which:

FIG. 1 is a schematic view of an exposure unit according to a first embodiment;

FIG. 2 is a schematic side view of an alignment system;

FIG. 3 is a plan view of a table as seen from above;

FIG. 4 illustrates another aperture different from the aperture shown in FIG. 3;

FIG. 5 illustrates another aperture different from the apertures shown in FIGS. 3 and 4; and

FIG. 6 is a schematic view of a laser-processing unit according to a second embodiment.

### DESCRIPTION OF THE PREFERRED EMBODIMENTS

Hereinafter, the preferred embodiments of the present invention are described with references to the attached drawings.

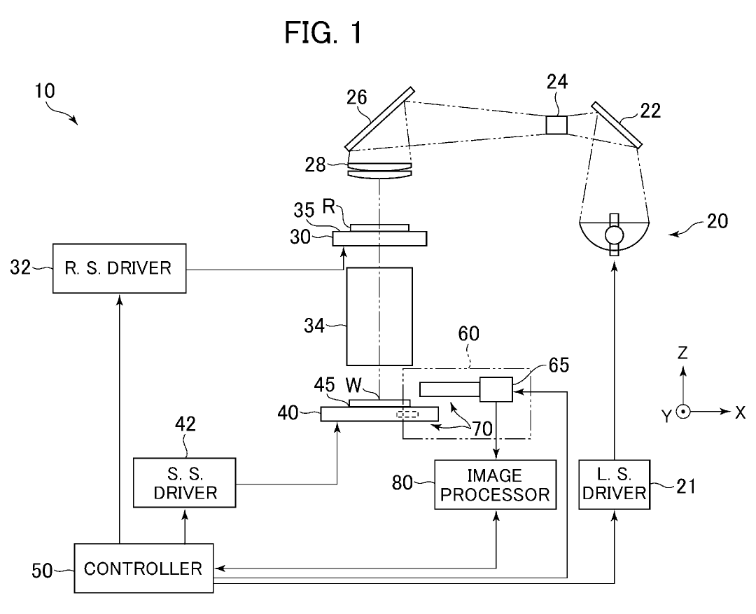

FIG. 1 is a block diagram of a projection exposure unit according to the first embodiment.

The projection exposure unit 10 is a projection aligner, which projects patterns formed in a reticle R onto a substrate W by a Step & Repeat method. The projection exposure unit 10 is equipped with a light source 20, a first stage 30, a projection optical system 34, and a second stage 40. The substrate W is herein a silicon wafer.

Illumination light emitted from the light source 20 enters an integrator 24 via a mirror 22. The illumination light with a unified distribution of light enters a collimator lens 28 via a mirror 26. Consequently, collimated light enters the reticle R.

The reticle R is mounted on a table 35 of the stage (first stage) 30 and a substrate w is mounted on a table 45 of the stage (second stage) 40. Herein, an X-axis and Y-axis, which are perpendicular to one another, are defined on the stage 30 and the stage 40. A Z-axis perpendicular to the X-Y plane is also defined.

The stage 30 and the stage 40 may move in the X-axis and Y-axis directions and further rotate around the Z-axis. The reticle stage 30 and the substrate stage 40 are driven by a reticle-stage driving unit 32 and a substrate-stage driving unit 42, respectively.

A pattern light that passes through the reticle R is formed on a photosensitive surface of the substrate W by the projection optical system 34. In an exposure process, the substrate stage 40 moves by a Step & Repeat method to form a reticle pattern onto the pattern areas (i.e., shot areas) in order. The reduced magnification of the projection optical system 34 is herein 0.25.

An alignment system 60 captures or images alignment marks provided on the substrate W in accordance to the off-axis method. The alignment system 60 is equipped with an imaging unit 65 with a camera or microscope and an alignment optical system 70. The alignment system 60 captures the alignment marks from the back-surface side of the substrate W, i.e., the stage side.

The camera provided in the imaging unit 65 may be moved along the X-axis and Y-axis by an actuator (not shown). An image processor 80 detects the positions of the alignment marks based on image signals fed from the alignment system 60.

A controller 50 controls the light source driver 21, the reticle stage driver 32, and the substrate stage driver 42 to carry out an exposure process by a Step & Repeat method. The controller 50 also controls the imaging unit 65 in the alignment system 60 to move the imaging unit 65 to a location in which the alignment marks can be captured.

The controller 50 may be constructed of a processor. The processor may be constructed of circuitry, i.e., hardware. On the other hand, processes performed by controller 50 may be carried out by firmware or software. In this case, a logic circuit or a CPU may be implemented.

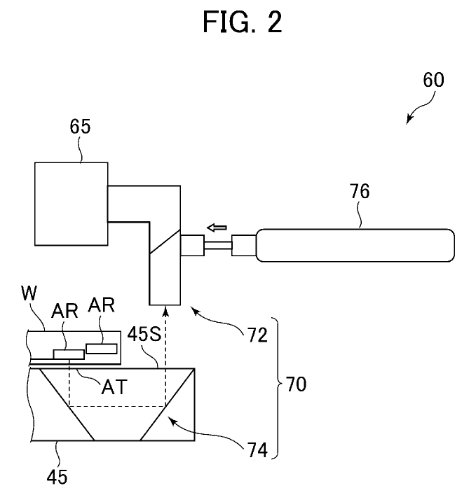

FIG. 2 is a schematic side view of the alignment system 60.

In the substrate W, a portion of the alignment marks AR are formed on the surface of the substrate W that makes contact with the surface 45S of the table 45. Also, a portion of the alignment marks AR are formed on the intermediate layer in the substrate W.

The alignment optical system 70 has a first optical system 72 and a second optical system 74. The first optical system 72 constitutes a relay optical system combined with an imaging optical system incorporated into the imaging unit 65. The second optical system 74 constitutes a relay optical system combined with the first optical system 72.

On the table 45, a plurality of apertures AT are formed on the surface 45S of the table 45. The alignment optical system 70 transmits or reflects illumination light emitted from an illumination unit 76 to illuminate the alignment marks AR on or in the substrate W via the apertures AT.

Light reflected off an alignment mark AR passes through the second optical system 74 and the first optical system 72 to reach an imaging surface of the imaging unit 65. Consequently, the alignment mark AR is detected as an image.

By viewing the alignment marks AR from the back-surface side of the substrate W i.e., the surface 45S of the table 45 (stage 40), the alignment system 60 can capture and image the alignment marks AR provided on the back-surface side and in the intermediate layer of the substrate W.

As for the detection of the alignment marks AR, a TTL (Through The Lens) method may be applied to the projection exposure unit 10 instead of the off-axis method. The second optical system 74 in the alignment optical system 70 may be combined with mirrors and prisms.

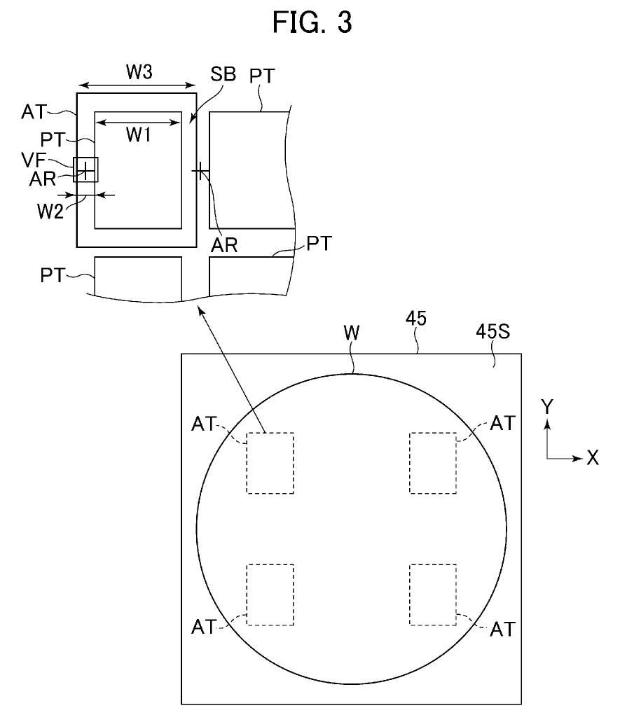

FIG. 3 is a plan view of the table 45 as seen from above. The substrate W is mounted at a given position. The formation of apertures AT will be explained with reference to FIG. 3.

The plurality of apertures AT is arranged on the table 45 to match the positions where the substrate W is mounted. Each aperture AT is rectangular shaped with the same size as one another and positioned equidistant from each other adjacent to the four conners of the substrate W. Herein, four apertures AT are formed on the table 45. Accordingly, four alignment systems 60 are provided in the projection exposure unit 10.

As shown in FIG. 3, dies (chips) PT are formed on the substrate W, which is a silicon wafer, and aligned in a grid. In an exposure process, a simultaneous exposure that exposes an entire single die PT as a one-shot area is carried out. Hereinafter, the die PT is called a “pattern area”.

The alignment marks AR are formed within scribe lines SB, which correspond to boundaries between neighboring pattern areas PT. The alignment marks AR shown in FIG. 3 are cross-shaped marks; however, other shapes may be used for the alignment marks AR. Note that the size of alignment mark AR shown in FIG. 3 is exaggerated.

The size or dimensions of the pattern area PT depends upon various characteristics or specifications, which include the size of the reticle R and the reduced magnification of the projection optical system 34. Also, the maximum size of the pattern area PT is determined in accordance to the semiconductor manufacturing process including the pre-process, in addition to the aforementioned characteristics and specifications. In the case of a six-inch reticle and reduced magnification of 0.25, the maximum size of the pattern area PT can be determined to be 26mm x 33mm.

In this embodiment, each aperture AT size is larger than the maximum size of the pattern area PT to allow the pattern area PT to be enclosed in the aperture AT. In other words, the entire pattern area AT can be seen via the aperture AT, as seen from the back-surface side. The width W3 of the aperture AT is greater than the sum of the width W1 of the pattern area PT and the width W2 of the alignment mark AR in the array direction of the alignment marks AR, i.e., the X-axis direction.

The size of an alignment mark AR is extremely minute compared to the size of the pattern area AT, because it takes dozens to hundreds of micrometers to align the substrate W with high accuracy. Accordingly, the size of the aperture AT can be set to be slightly larger than the maximum size of the pattern area PT in the X-axis direction. For example, the size of the aperture AT is greater than that of the pattern area PT by 1mm to 2mm. Therefore, the size of the aperture AT may be determined based on not including a neighboring pattern area PT in the aperture AT. In other words, only one entire pattern area PT is aligned directly opposite to one aperture AT, with no part of a neighboring pattern area PT directly opposite the aperture, thereby the neighboring pattern area AT cannot be seen via the aperture AT, as seen from the back-surface side.

By setting the aperture AT size as described above, at least one alignment mark AR can be included in an area corresponding to the aperture AT when mounting the substrate W on the table 45 in a given position. Thus, the imaging unit 65 can capture at least one alignment mark AR via the aperture AT.

The visual field VF of the imaging device 65 is set to an extremely narrow area to correctly detect the position of the minute (dozens to hundreds of micrometers) alignment mark AR. The visual field VF is herein set to dimensions 1mm x 1mm. Since at least one alignment mark AR is located within an area corresponding to the aperture AT, the imaging unit 65 can capture an alignment mark AR located within the visual field VF, without resetting the substrate W.

On the other hand, the moving distance of the imaging unit 65 is suppressed since the size of the aperture AT corresponds to a size that is constrained not to include the neighboring pattern area PT. When the size of the pattern area PT is smaller than the maximum size, at least one alignment mark AR can obviously be captured.

The alignment marks AR may be formed on the edge lines of the pattern area PT or within the pattern area PT. In this case, at least one alignment mark AR can be captured since at least one alignment mark AR can be located within an area corresponding to the aperture AT. The aperture AT may be in the form of another shape and the forming position of the aperture AT is arbitrary as long as it meets the condition that the size of the aperture AT meets the above size.

In the projection exposure unit 10, a standard-position correcting process is carried out for the alignment system 60. The imaging unit 65 captures standard marks (not shown) provided on the table 45. Based on the position coordinates of the alignment marks AR, the controller 50 carries out a global alignment. Concretely, the controller 50 detects deviations of straightness, rotation and scaling due to a linear expansion and contraction of the substrate W in a global area, based on data associated with the position coordinates of the alignment marks AR, which are output from the image processor 80. Then, corrected values (off-set values, a scaling value, and a rotation correcting value) are calculated to adjust the positions of the stage 30 and the stage 40.

One alignment system may be provided in the projection exposure unit 10 instead of the four alignment systems. In this case, one alignment system has one imaging unit that is movable in the X-axis and Y-axis directions, and four secondary optical systems are arranged at positions corresponding to the locations of the four apertures AT.

As for the number of apertures, at least three apertures may be formed so that the global alignment can be carried out. A die-by-die alignment may be applied instead of the global alignment. In this case, the number of openings may be one. The forming of the aperture AT may be determined so that the aperture AT is aligned directly opposite to one pattern area and part of the boundary between the neighboring pattern areas.

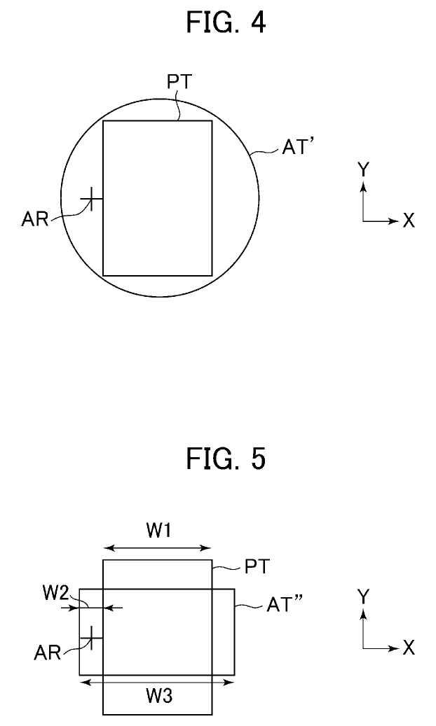

FIG. 4 illustrates another aperture different from the apertures shown in FIG. 3. In FIG. 4, the aperture AT’ is formed in a circle. The width of the aperture AT’ is greater than the sum of the widths of the pattern area PT and the alignment mark AR in the X-axis direction.

FIG. 5 illustrates another aperture different from the apertures shown in FIGS. 3 and 4. In FIG. 5, the aperture AT” is rectangular and aligned partially opposite to the pattern area PT. The entire pattern area PT is not included within an area corresponding to the aperture AT”. However, the width W3 of the aperture AT” is greater than the sum of the width W1 of the pattern area PT and the width W2 of the alignment mark AR in the X-axis direction. Since the aperture AT includes part of the scribe lines SB in the X-axis direction, the alignment mark AR can be captured by the imaging unit 65. Various shapes and sizes of apertures may be formed on the table 45.

In this way, the projection exposure unit 10 is equipped with the stage 40 having the table 45 with the apertures AT and the alignment system 60. The substrate W, which is a silicon wafer, is mounted on the surface 45S of the table 45. Each aperture AT size includes one of the pattern areas (dies) arrayed in a grid and at least one alignment mark AR.

Thus, various arrays of the pattern areas (dies) can be realized. The formation of the pattern areas is not limited by the shape or size of an aperture formed on the table 45 when carrying out an alignment by the global method.

As for the substrate W, a substrate other than a silicon wafer, e.g., a printed wiring board, may be applied. In this case, alignment marks are formed within boundaries of neighboring pattern areas and an aperture that allows at least one alignment mark to be captured is formed on the surface 45S of the table 45.

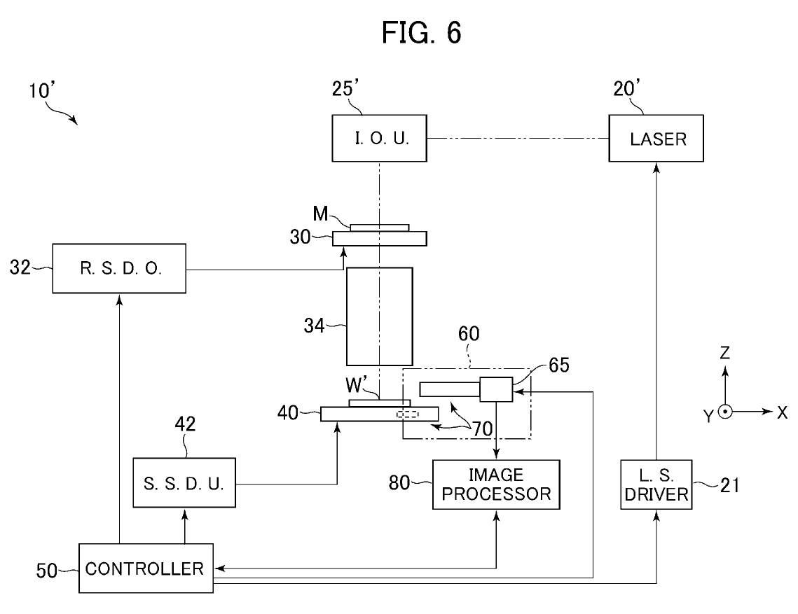

FIG. 6 is a block diagram of a laser-processing unit according to the second embodiment. Note that the same numerical references are used for the components that are the same as those used in the first embodiment.

The laser-processing unit 10’ is equipped with a laser 20’ and an illumination optical unit 25’. A mask (photomask) is mounted on the stage 30 and a board type of substrate W’ is mounted on the stage 40. In a laser process, the substrate W’ is processed by a laser beam that passes through the mask M. The alignment system 60 is the same as that of the first embodiment.

The size of aperture AT formed on the table 45 is determined in accordance to the size of a pattern area, which depends upon characteristics or specifications of the laser unit 10’ and the manufacturing process. Especially, the size of aperture AT is determined with respect to the maximum size of the photomask used in the laser-processing unit 10’.

Finally, it will be understood by those skilled in the arts that the foregoing description is of preferred embodiments of the device, and that various changes and modifications may be made to the present invention without departing from the spirit and scope thereof.

The present disclosure relates to subject matter contained in Japanese Patent Application No. 2025-013077 (filed on January 29, 2025), which is expressly incorporated herein by reference, in its entirety.

1. An apparatus for forming a pattern onto a substrate, comprising:
a table with a surface, a substrate with a plurality of pattern areas being mounted on said surface, at least one aperture being formed in said surface; and
a measuring system configured to capture alignment marks formed on or in said substrate from the surface side, via said aperture, said aperture having a size that includes one pattern area and part of the surrounding boundary.

2. The apparatus according to claim 1, wherein the width of said aperture is greater than the sum of the width of a pattern area and the width of an alignment mark in one direction.

3. The apparatus according to claim 1, wherein at least three apertures are formed on the surface.

4. The apparatus according to claim 1, wherein the substrate is a semiconductor wafer.

5. The apparatus according to claim 1, wherein the size of the aperture is greater than the size of each pattern area that depends upon a maximum size of a reticle.

6. The apparatus according to claim 1, wherein the alignment marks are provided outside of each pattern area.

7. The apparatus according to claim 1, wherein the plurality of pattern areas is arranged in a grid.

8. The apparatus according to claim 1, wherein said apparatus is a projection exposure unit.

9. The apparatus according to claim 1, wherein said apparatus is a laser-processing unit.

10. An alignment system comprising:
a table with a surface, a substrate with a plurality of pattern areas being mounted on said surface, at least one aperture being formed on said surface;
a measuring system configured to capture alignment marks formed on or in said substrate from the surface side, via said aperture; and
a processor configured to calculate alignment-correcting values based on the positions of the alignment marks, said aperture having a size that includes one pattern area and part of the surrounding boundary.

11. A method for aligning a substrate, comprising:
a) mounting a substrate with a plurality of pattern areas on a surface of a table, at least one aperture being formed on said surface, said aperture having a size that includes one pattern area and part of the surrounding boundary; and
b) capturing alignment marks formed on or in said substrate from the surface side, via said aperture; and
c) calculating alignment-correcting values based on the positions of the alignment marks.
